(19) United States
(12) Patent Application Publication
(10) Pub. No.: US 2016/0086813 A1
(43) Pub. Date: Mar. 24, 2016

(54) METHOD OF FABRICATING SEMICONDUCTOR DEVICE

(71) Applicant: Samsung Electronics Co., Ltd., Suwon-si (KR)

(72) Inventors: Ye-hwan KIM, Seoul (KR); Un-gyu PAIK, Seoul (KR); Ji-hoon SEO, Seoul (KR); Sang-kyun KIM, Yongin-si (KR); Jong-woo KIM, Hwaseong-si (KR); Dong-jun LEE, Seoul (KR)

(21) Appl. No.: 14/708,544

(22) Filed: May 11, 2015

(30) Foreign Application Priority Data
Sep. 24, 2014 (KR) 10-2014-0127691

(51) Int. Cl. H01L 21/306; H01L 29/66; H01L 21/8234

(52) U.S. Cl. CPC H01L 21/30625; H01L 21/823437; H01L 29/66545

(57) ABSTRACT

A method of fabricating a semiconductor device includes forming an active region in a semiconductor substrate, forming a plurality of dummy gates on the active region, the plurality of dummy gates having a gate mask disposed thereon, forming an interlayer insulating layer on the gate mask, and performing a one-time chemical mechanical polishing (CMP) process by using a slurry composition capable of polishing the interlayer insulating layer and the gate mask until top surfaces of the dummy gates are exposed.

### CROSS-REFERENCE TO RELATED APPLICATION

This application claims the benefit of Korean Patent Application No. 10-2014-0127691, filed on Sep. 24, 2014, in the Korean Intellectual Property Office, the disclosure of which is incorporated herein in its entirety by reference.

### BACKGROUND

1. Field

Some example embodiments of the inventive concepts relate to a method of fabricating a semiconductor device using a slurry composition for a chemical mechanical polishing (CMP) process, and more particularly, to a method of fabricating a semiconductor device using a slurry composition for a CMP process, by which a silicon nitride layer and a silicon oxide layer may be simultaneously polished using a one-time process.

2. Description of the Related Art

A replacement metal gate (RMG) process for a device to which a gate-last scheme is applied may include performing a CMP process on a silicon oxide layer by using a silicon nitride layer as a polishing stop layer, removing the silicon nitride layer by using an etch back process, and performing a CMP process on the silicon oxide layer again by using a polysilicon (poly-Si) layer as a polishing stop layer.

### SUMMARY

Some example embodiments of the inventive concepts provide a method of fabricating a semiconductor device using a gate-last scheme, which may include a process of removing a silicon nitride layer and a silicon oxide layer using a one-time chemical mechanical polishing (CMP) process by using a slurry composition having relatively high polishing selectivities of the silicon nitride layer and the silicon oxide layer to a polysilicon (poly-Si) layer.

According to an example embodiment of the inventive concepts, a method of fabricating a semiconductor device includes forming an active region in a semiconductor substrate, forming a plurality of dummy gates on the active region, the plurality of dummy gates having a gate mask disposed thereon, forming an interlayer insulating layer on the gate mask, and performing a one-time CMP process using a slurry composition capable of polishing the interlayer insulating layer and the gate mask until top surfaces of the dummy gates are exposed.

The gate mask may include a silicon nitride layer, the dummy gates may include polysilicon, and the interlayer insulating layer may include a silicon oxide layer. The slurry composition may include a polishing agent, a silicon nitride layer a polishing accelerator, a polysilicon layer polishing inhibitor, a silicon oxide layer polishing control agent, a pH control agent, and a remaining percentage by weight of solvent.

The slurry composition may have a polishing selectivity for a silicon nitride layer to a silicon oxide layer ranging from about 1:1 to about 3:1.

The slurry composition may have a polishing selectivity for a silicon nitride layer to a polysilicon layer ranging from about 50:1 to about 300:1.

The slurry composition may have a polishing selectivity for a silicon oxide layer to a polysilicon layer ranging from about 30:1 to about 200:1.

The semiconductor device may include a three-dimensional memory array.

The polishing agent may include at least one of silica particles, alumina particles, ceria particles, zirconia particles, and titania particles.

The silicon nitride layer polishing accelerator may include at least one of isoleucine, alanine, glycine, glutamine, threonine, serine, asparagine, tyrosine, cysteine, valine, and leucine.

The silicon nitride layer polishing accelerator may have a content of about 0.01% by weight to about 10% by weight in the slurry composition.

The polysilicon layer polishing inhibitor may include at least one of polyvinyl alcohol (PVA), ethylene glycol (EG), glycerine, polyethylene glycol (PEG), polypropylene glycol (PPG), polyvinyl pyrrolidone (PVP), poly(acrylic acid) (PAA), ammonium salts of PAA, poly(methacrylic acid) (PMAA), ammonium salts of PMAA, polyacrylic maleic acid, an alkyl sodium sulfonate fluorosurfactant, a polyoxyethylene fluorosurfactant, and a nonionic ethoxylated fluorosurfactant.

The polysilicon layer polishing inhibitor may have a content of about 0.0001% by weight to about 1% by weight in the slurry composition.

The silicon oxide layer polishing control agent may include at least one of 1-2-hydroxyethyl-2-pyrrolidone, 4-hydroxyethyl-2-pyrrolidone, maleic anhydride, maleic hydrazide, and malemide.

The silicon oxide layer polishing control agent may have a content of about 0.01% by weight to about 10% by weight in the slurry composition.

The pH control agent may include at least one of ammonia, ammonium methyl propanol (AMP), tetra methyl ammonium hydroxide (TMAH), potassium hydroxide, sodium hydroxide, magnesium hydroxide, rubidium hydroxide, cesium hydroxide, sodium bicarbonate, sodium carbonate, triethanolamine, tromethamine, niacinamide, nitric acid, sulphuric acid, phosphoric acid, hydrochloric acid, acetic acid, citric acid, glutaric acid, glycolic acid, formic acid, lactic acid, malic acid, malonic acid, maleic acid, oxalic acid, phthalic acid, succinic acid, and tartaric acid.

According to another example embodiment of the inventive concepts, a method of fabricating a semiconductor device includes forming an active region in a semiconductor substrate, forming a plurality of polysilicon layer patterns on the active region, the plurality of polysilicon layer patterns having a silicon nitride layer disposed thereon, forming a silicon oxide layer on the silicon nitride layer, and performing a one-time CMP process using a slurry composition to remove the silicon nitride layer and the silicon oxide layer until a top surface of the polysilicon layer patterns are exposed, the slurry composition containing a polishing agent, a silicon nitride layer polishing accelerator, a polysilicon layer polishing inhibitor, a silicon oxide layer polishing control agent, a pH control agent, and a remaining percentage by weight of solvent.

According to another example embodiment of the inventive concepts, a method of fabricating a semiconductor device includes forming a plurality of poly-Si patterns on a semiconductor substrate, forming a silicon nitride layer on the plurality of poly-Si patterns, forming a silicon oxide layer covering the silicon nitride layer and the semiconductor substrate, and performing a chemical mechanical polishing (CMP) process using a slurry composition to remove the silicon nitride layer and the silicon oxide layer until top surfaces of the plurality of poly-Si patterns are exposed, the slurry composition having a higher polishing selectivity for the silicon nitride layer and the silicon oxide layer than for the poly-Si patterns.

The slurry composition may include a polishing agent, a silicon nitride layer polishing accelerator, a polysilicon layer polishing inhibitor, a silicon oxide layer polishing control agent, a pH control agent, and a remaining percentage by weight of solvent.

The slurry composition may have the polishing selectivity for the silicon nitride layer to the silicon oxide layer ranging from about 1:1 to about 3:1.

The slurry composition may have the polishing selectivity for the silicon nitride layer to the poly-Si patterns ranging from about 50:1 to about 300:1.

The slurry composition may have the polishing selectivity the silicon oxide layer to the poly-Si patterns ranging from about 30:1 to about 200:1.

### BRIEF DESCRIPTION OF THE DRAWINGS

Example embodiments of the inventive concepts will be more clearly understood from the following detailed description taken in conjunction with the accompanying drawings in which:

FIGS. 1 through 4 are cross-sectional views illustrating sequential processes of a method of fabricating a semiconductor device according to an example embodiment of the inventive concepts and a conventional method of fabricating a semiconductor device;

FIG. 5 is a graph showing a polishing selectivity depending on the presence or absence of a silicon nitride layer polishing accelerator, a polysilicon (poly-Si) layer polishing inhibitor, and a silicon oxide layer polishing control agent;

FIG. 6 is a circuit diagram of an inverter including a semiconductor device fabricated using a method of fabricating a semiconductor device according to an example embodiment of the inventive concepts;

FIG. 7 is a schematic diagram of a card including a semiconductor device fabricated using a method of fabricating a semiconductor device according to an example embodiment of the inventive concepts;

FIG. 8 is a schematic diagram of an electronic system including a semiconductor device fabricated using a method of fabricating a semiconductor device according to an example embodiment of the inventive concepts; and

FIG. 9 is a schematic perspective view of an electronic device to which a semiconductor device fabricated using a method of fabricating a semiconductor device according to an example embodiment of the inventive concepts is applied.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list.

The inventive concepts will now be described more fully hereinafter with reference to the accompanying drawings, in which example embodiments of the inventive concepts are shown. The inventive concepts may, however, be embodied in different forms and should not be construed as limited to the embodiments set forth herein. Rather, these embodiments are provided so that this disclosure is thorough and complete and fully conveys the scope of the inventive concepts to one skilled in the art. Like numbers refer to like elements throughout. In the drawings, the sizes and relative sizes of layers and regions may be exaggerated for clarity and thus, the inventive concepts should not be limited by the sizes and relative sizes of the layers and the regions.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms first, second, etc. may be used herein to describe various elements, components, regions, layers and/or sections, these elements, components, regions, layers and/or sections should not be limited by these terms. Thus, a first element, component, region, layer or section discussed below could be termed a second element, component, region, layer or section without departing from the teachings of the inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the inventive concepts. As used herein, the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless explicitly so defined herein.

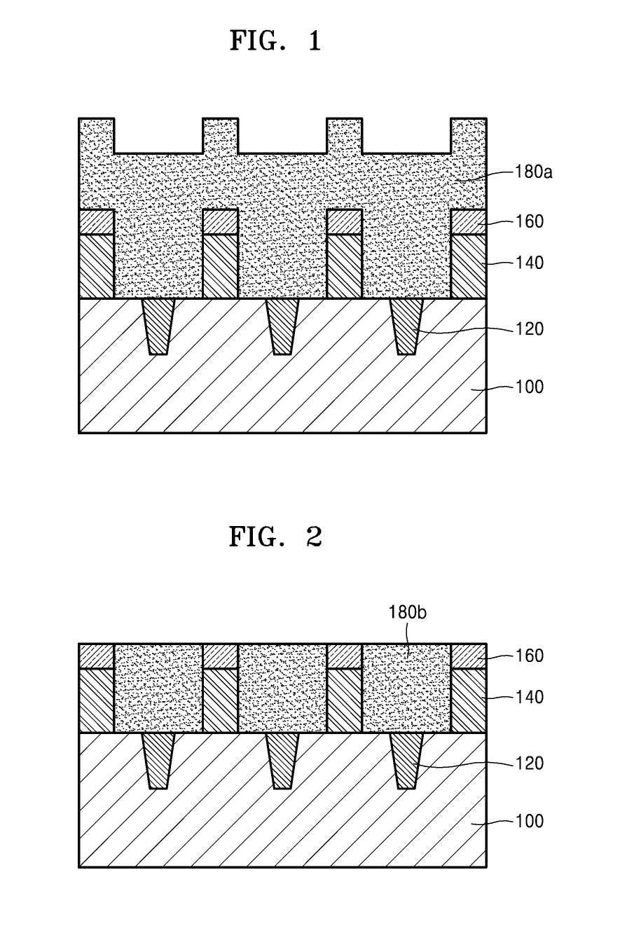

Hereinafter, example embodiments of the inventive concepts will be described in detail with reference to FIGS. 1 through 9.

FIGS. 1 through 4 are cross-sectional views illustrating sequential processes of a method of fabricating a semiconductor device according to an example embodiment of the inventive concepts and a conventional method of fabricating a semiconductor device.

In a conventional semiconductor fabrication process, as shown in FIGS. 1 through 4, a replacement metal gate (RMG) process for a device to which a gate-last scheme is applied may include performing a chemical mechanical polishing (CMP) process on an interlayer insulating layer using a gate mask as a polishing stop layer, removing the gate mask by using an etchback process, and performing a CMP process on the interlayer insulating layer again by using a dummy gate as a polishing stop layer.

In most cases, the gate mask may include a silicon nitride layer, the dummy gate may include polysilicon (poly-Si), and the interlayer insulating layer may include a silicon oxide layer.

Referring to FIG. 1, an active region 120 may be formed in a semiconductor substrate 100. To form an RMG of a gate-last-scheme applied device, a dummy gate 140 may be formed of poly-Si, a gate mask 160 may be formed using a silicon nitride layer on the dummy gate 140, and an interlayer insulating layer 180a may be formed using a silicon oxide layer on the gate mask 160.

Referring to FIG. 2, a CMP process may be performed on an interlayer insulating layer 180b formed on the gate mask 160, and stopped by using the gate mask 160 as a polishing stop layer. That is, a first CMP process may be performed by using a slurry composition that has a higher polishing rate against a silicon oxide layer than against a silicon nitride layer using a polishing selectivity between the silicon nitride layer and the silicon oxide layer.

Referring to FIG. 3, when a top surface of the gate mask 160 is exposed by performing the first CMP process, the gate mask 160 may be removed using an etchback process.

Referring to FIG. 4, when the gate mask 160 is removed using the etchback process and a top surface of the interlayer insulating layer 180b becomes at a higher level than a top surface of the dummy gate 140, a CMP process may be performed on the interlayer insulating layer 180b, and stopped by using the dummy gate 140 as a polishing stop layer to form the interlayer insulating layer 180c. That is, a second CMP process may be performed by using a slurry composition that has a higher polishing rate against a silicon oxide layer than against a poly-Si layer using a polishing selectivity between the poly-Si layer and the silicon oxide layer.

By comparison, during a semiconductor fabrication process according to the inventive concepts, in the semiconductor structure shown in FIG. 1, a CMP process may be performed on the interlayer insulating layer 180a and the gate mask 160, and stopped using the dummy gate 140 as a polishing stop layer as described with reference to FIG. 4. That is, a one-time CMP process may be performed using a common slurry composition that has higher polishing rates against a silicon nitride layer and a silicon oxide layer than against a poly-Si layer using a polishing selectivity among the poly-Si layer, the silicon nitride layer, and the silicon oxide layer.

Accordingly, in the example embodiment of the inventive concepts, a silicon nitride layer and a silicon oxide layer may be polished at one time by using a poly-Si layer as a polishing stop layer and using a common slurry composition having higher polishing selectivities of the silicon nitride layer and the silicon oxide layer to the poly-Si layer. Thus, as compared with a conventional process, process simplicity may be embodied, fabrication costs may be reduced, and throughput per unit time may increase.

To perform a method of fabricating a semiconductor according to the inventive concepts, a CMP process may be performed by using a common slurry composition having high polishing selectivities of a silicon nitride layer and a silicon oxide layer to a poly-Si layer. Accordingly, contents of the common slurry composition will be examined.

A common slurry composition for a CMP process according to an example embodiment of the inventive concepts may be a composition that contains a polishing agent, a silicon nitride layer polishing accelerator, a poly-Si layer polishing inhibitor, a silicon oxide layer polishing control agent, a pH control agent, and a remaining percentage by weight of solvent.

The silicon nitride layer polishing accelerator and poly-Si layer polishing inhibitor according to the present example embodiment may increase polishing rates of the silicon nitride layer and the silicon oxide layer and simultaneously, inhibit a polishing rate of the poly-Si layer due to interaction between the silicon nitride layer polishing accelerator and poly-Si layer polishing inhibitor.

The silicon nitride layer polishing accelerator according to an example embodiment of the inventive concepts may include at least one selected from the group consisting of isoleucine, alanine, glycine, glutamine, threonine, serine, asparagine, tyrosine, cysteine, valine, and leucine.

Content of the silicon nitride layer polishing accelerator may be about 0.01% by weight to about 10% by weight, based on the total weight of the common slurry composition. When the content of the silicon nitride layer polishing accelerator is less than the content range, an effect (i.e., a rise in polishing rate of a silicon nitride layer) that may be expected by adding the silicon nitride layer polishing accelerator may be unsatisfactory. Conversely, when the content of the silicon nitride layer polishing accelerator exceeds the content range, it may be difficult to control polishing selectivities of a silicon nitride layer to a silicon oxide layer and a poly-Si layer.

The poly-Si layer polishing inhibitor according to the present example embodiment may include at least one selected from the group consisting of a non-ionic polymer, an anionic polymer, or a fluorosurfactant. The non-ionic polymer may include at least one selected from the group consisting of polyvinyl alcohol (PVA), ethylene glycol (EG), glycerine, polyethylene glycol (PEG), polypropylene glycol (PPG), and polyvinyl pyrrolidone (PVP). The anionic polymer may include at least one selected from the group consisting of poly(acrylic acid) (PAA), ammonium salts of PAA, poly(methacrylic acid) (PMAA), ammonium salts of PMAA, and polyacrylic maleic acid. The fluorosurfactant may include at least one selected from the group consisting of an alkyl sodium sulfonate fluorosurfactant, a polyoxyethylene fluorosurfactant, a nonionic ethoxylated fluorosurfactant.

When content of the poly-Si layer polishing inhibitor is about 0.0001% by weight to about 1% by weight, preferably, about 0.01% by weight to about 1% by weight, and more preferably, about 0.01% by weight to about 0.5% by weight, based on the total weight of the common slurry composition. When the content of the poly-Si layer polishing inhibitor is less than the content range, an effect (i.e., inhibition of a polishing rate of a poly-Si layer) that may be expected by adding the poly-Si layer polishing inhibitor may be unsatisfactory. Conversely, when the content of the poly-Si layer polishing inhibitor exceeds the content range, a function of the silicon nitride layer polishing accelerator may be hindered.

The silicon oxide layer polishing control agent according to an example embodiment of the inventive concepts may include at least one selected from the group consisting of 1-2-hydroxyethyl-2-pyrrolidone, 4-hydroxyethyl-2-pyrrolidone, maleic anhydride, maleic hydrazide, and malemide.

Content of the silicon oxide layer polishing control agent may be about 0.01% by weight to about 10% by weight, based on the total weight of the common slurry composition. When the content of the silicon oxide layer polishing control agent is less than the content range, an effect (control of polishing rate of a silicon oxide layer) that may be expected by adding the silicon oxide layer polishing control agent may be unsatisfactory. Conversely, when the content of the silicon oxide layer polishing control agent exceeds the content range, a function of the poly-Si layer polishing inhibitor may be hindered.

The polishing agent according to an example embodiment may include a metal oxide, such as silica (SiO₂), alumina (Al₂O₃), ceria (CeO₂), zirconia (ZrO₂), or titania (TiO₂). In particular, when ceria is used as the polishing agent, undesirable phenomena caused by a difference in density between a pattern region and a non-pattern region may be reduced. A mixture of at least two of the above-described metal oxides may be used as the polishing agent.

Content of the polishing agent may be about 0.01% by weight to about 1% by weight, based on the total weight of the common slurry composition.

Polishing particles of the polishing agent may have a size of about 3 nm to about 300 nm. Here, the size of each of the polishing particles may refer to a diameter, which is a maximum value of a distance between two points in each of the polishing particles. An average diameter of the polishing particles may be controlled to be within a range of about 3 nm to about 3 nm in view of the fact that when the size of the polishing particles is excessively small, a polishing rate for planarizing a substrate is reduced, while when the size of the polishing particles is excessively large, dispersion stability may be degraded, planarization of the substrate may precluded, and mechanical defects, such as scratches on a polished surface, may occur. However, the average diameter of the polishing particles is not limited thereto.

The solvent according to an example embodiment may be deionized water (DIW). The solvent may serve as a solvent for materials, such as the silicon nitride layer polishing accelerator and/or the poly-Si layer polishing inhibitor, which are completely dissolved in a solvent, but the solvent may serve as a dispersion medium for fine metal particles, such as the polishing agent. In other words, the solvent may serve as both a solvent and a dispersion medium, but the solvent will be collectively referred to as a solvent for brevity.

The pH control agent according to an example embodiment may include at least one selected from the group consisting of alkali solutions, such as ammonia, ammonium methyl propanol (AMP), tetra methyl ammonium hydroxide (TMAH), potassium hydroxide, sodium hydroxide, magnesium hydroxide, rubidium hydroxide, cesium hydroxide, sodium bicarbonate, sodium carbonate, triethanolamine, tromethamine, and niacinamide, and/or acidic solutions, such as nitric acid, sulphuric acid, phosphoric acid, hydrochloric acid, acetic acid, citric acid, glutaric acid, glycolic acid, formic acid, lactic acid, malic acid, malonic acid, maleic acid, oxalic acid, phthalic acid, succinic acid, and tartaric acid.

The common slurry composition for the CMP process may have a pH value of about 5 to about 10, and more specifically, about 6 to about 8. In ceria slurry, a negative zeta-potential may be embodied in a neutral zone. When the common slurry composition has an excessively high pH value, a polishing selectivity may be degraded, while the common slurry composition has an excessively low pH value, a polishing rate may be excessively high. When the common slurry composition has an inappropriate pH value, the pH value may be controlled by using the pH control agent.

Various Experimental examples will be described for clarity.

### EXPERIMENTAL EXAMPLE 1

To examine the influence of the silicon nitride layer polishing accelerator of the common slurry composition upon a polishing process, seven kinds of common slurry compositions were prepared. Experiment No. 1 was a slurry composition in which a polishing agent contained about 1% by weight of ceria, Experiment No. 2 was a slurry composition in which a polishing agent contained about 1% by weight of ceria and about 0.1% by weight of isoleucine, Experiment No. 3 was a slurry composition in which a polishing agent contained about 1% by weight of ceria and about 0.1% by weight of alanine, Experiment No. 4 was a slurry composition in which a polishing agent contained about 1% by weight of ceria and about 0.1% by weight of glycine, Experiment No. 5 was a slurry composition in which a polishing agent contained about 1% by weight of ceria and about 0.1% by weight of glutamine, Experiment No. 6 was a slurry composition in which a polishing agent contained about 1% by weight of ceria and about 0.1% by weight of threonine, and Experiment No. 7 was a slurry composition in which a polishing agent contained about 1% by weight of ceria and about 0.1% by weight of serine.

As sample wafers, a wafer having a silicon nitride layer formed on a silicon substrate to a thickness of about 2000 angstroms (Å), a wafer having a silicon oxide layer formed on a silicon substrate to a thickness of about 2000 Å, and a wafer having a poly-Si layer formed on a silicon substrate to a thickness of about 2000 Å were used.

An 8-inch EBARA equipment was used as a polishing apparatus, and IC1000 stacked pads (from Rodel Inc.) were used as pads. Polishing processes were performed in conditions where a downward pressure was about 216 hPa, a retaining ring pressure was 255 hPa, a platen speed was about 100 rpm, a head speed was about 101 rpm, and a slurry flow rate was about 200 ml/min.

Removed amounts of layers were measured using an optical thickness measuring apparatus.

Examination results of the respective common slurry compositions were shown in Table 1.

TABLE 1

| | Common | | | | |
|---|---|---|---|---|---|
| | slurry composition | Polishing | | | Polishing |
| No. | (1 wt % ceria + 1 wt % | rate (Å/min) | | | selectivity |
| 1 | the following additives) | SiN | SiO₂ | Poly-Si | SiN:SiO₂:Poly-Si |
| 2 | No additive | 540 | 1539 | 646 | 0.8:2.4:1 |
| 3 | Isoleucine | 514 | 517 | 675 | 0.8:0.8:1 |
| 4 | Alanine | 638 | 1077 | 590 | 1.1:1.8:1 |
| 5 | Glycine | 652 | 1265 | 566 | 1.2:2.2:1 |
| 6 | Glutamine | 877 | 513 | 512 | 1.7:1.0:1 |
| 7 | Threonine | 828 | 600 | 542 | 1.5:1.1:1 |
| 8 | Serine | 727 | 723 | 673 | 1.1:1.1:1 |

As can be seen from Table 1, when a silicon nitride layer polishing accelerator was not added to the slurry composition in which the polishing agent contained about 1% by weight of ceria according to Experimental No. 1, a polishing selectivity for a silicon nitride layer to a silicon oxide layer was lower than in other experiments using slurry compositions to which a silicon nitride layer polishing accelerator was added. When the slurry compositions according to Experiments Nos. 2, 5, 6, and 7 were used, it can be seen that the polishing selectivity for the silicon nitride layer to the silicon oxide layer was about 1 or more. Also, in Experiments Nos. 3 and 4, the polishing selectivity for the silicon nitride layer to the silicon oxide layer was lower than in Experiments Nos. 2, 5, 6. And 7.

### EXPERIMENTAL EXAMPLE 2

Since the slurry composition fabricated according to Experimental example 1 had a high poly-Si polishing rate, PEG was added at a content of about 0.05% by weight to the poly-Si polishing inhibitor so that a poly-Si layer could act as an effective polishing stop layer. PEG was adsorbed to the surface of the poly-Si layer with an interaction between the poly-Si layer and PEG due to a hydrophobic group to inhibit polishing of the poly-Si layer.

Sample wafers, a polishing apparatus, and pads were the same as those of Experimental example 1. Polishing conditions and a method of measuring experimental results were the same as in Experimental example 1.

Examination results of respective common slurry compositions were shown in Table 2.

TABLE 2

| | Common slurry composition | Polishing rate (Å/min) | | | Polishing selectivity |
|---|---|---|---|---|---|
| No. | (1 wt % ceria + the following additives) | SiN | SiO₂ | Poly-Si | SiN:SiO₂:Poly-Si |
| 8 | PEG 0.05 wt % | 466 | 1160 | 10 | 47:116:1 |
| 9 | Glycine 0.1 wt % + PEG 0.05 wt % | 846 | 1531 | 12 | 71:128:1 |
| 10 | Threonine 0.1 wt % + PEG 0.05 wt % | 1212 | 1373 | 14 | 87:98:1 |

As can be seen from Table 2, when a slurry composition formed by adding about 0.05% by weight of PEG to a polishing agent containing about 1% by weight of ceria was used according to Experiment No. 8, a polishing selectivity for a silicon nitride layer to a poly-Si layer was lower than in other experiments. When a slurry composition formed by adding about 0.1% by weight of glycine serving as a nonpolar amino acid and about 0.05% by weight of PEG to a slurry in which a polishing agent contained about 1% by weight of ceria was used according to Experiment No. 9, the polishing selectivity for the silicon nitride layer to the poly-Si layer was intermediate. When a slurry composition formed by adding about 0.1% by weight of threonine serving as a polar amino acid and about 0.05% by weight of PEG to a slurry in which a polishing agent contained about 1% by weight of ceria was used according to Experimental No. 10, the polishing selectivity for the silicon nitride layer to the poly-Si layer was higher than in other experiments.

### EXPERIMENTAL EXAMPLE 3

Although the slurry composition fabricated according to Experimental example 2 could use the poly-Si layer as a polishing stop layer, since a polishing rate of the silicon oxide layer increased, a polishing selectivity of the common slurry composition was controlled by adding the silicon oxide layer polishing control agent to the common slurry composition, so that the polishing rate of the silicon oxide layer could be reduced.

Sample wafers, a polishing apparatus, and pads were the same as those of Experimental example 1. Polishing conditions and a method of measuring experimental results were the same as in Experimental example 1.

Examination results of the respective common slurry compositions were shown in Table 3.

TABLE 3

| | Common slurry composition | Polishing rate (Å/min) | | | Polishing selectivity |
|---|---|---|---|---|---|
| No. | (1 wt % ceria + the following additives) | SiN | SiO₂ | Poly-Si | SiN:SiO₂:Poly-Si |
| 11 | Threonine 0.1 wt % + PEG 0.05 wt % | 1212 | 1374 | 14 | 87:98:1 |
| 12 | Threonine 0.1 wt % + PEG 0.05 wt % + | 627 | 592 | 9 | 70:66:1 |
| | 1-2-hydroxyethyl-2-pyrrolidone 0.1 wt % | | | | |
| 13 | Threonine 0.1 wt % + PEG 0.05 wt % + | 862 | 600 | 13 | 66:46:1 |
| | 4-hydroxyethyl-2-pyrrolidone 0.1 wt % | | | | |

As can be seen from Table 3, when a common slurry composition formed by adding about 0.1% by weight of threonine and adding about 0.05% by weight of PEG to a polishing agent containing about 1% by weight of ceria was used according to Experiment No 11, a polishing selectivity for a silicon nitride layer to a silicon oxide layer was lower than in other experiments. When a common slurry composition formed by adding about 0.1% by weight of threonine, about 0.05% by weight of PEG, and about 0.1% by weight of 1-2-hydroxyethyl-2-pyrrolidone to a polishing agent containing about 1% by weight of ceria was used according to Experiment No. 12, the polishing selectivity for the silicon nitride layer to the silicon oxide layer was intermediate. When a common slurry composition formed by adding about 0.1% by weight of threonine, about 0.05% by weight of PEG, and about 0.1% by weight of 4-hydroxyethyl-2-pyrrolidone to a polishing agent containing about 1% by weight of ceria was used according to Experimental No. 13, a polishing selectivity for the silicon nitride layer to the silicon oxide layer was higher than in other experiments.

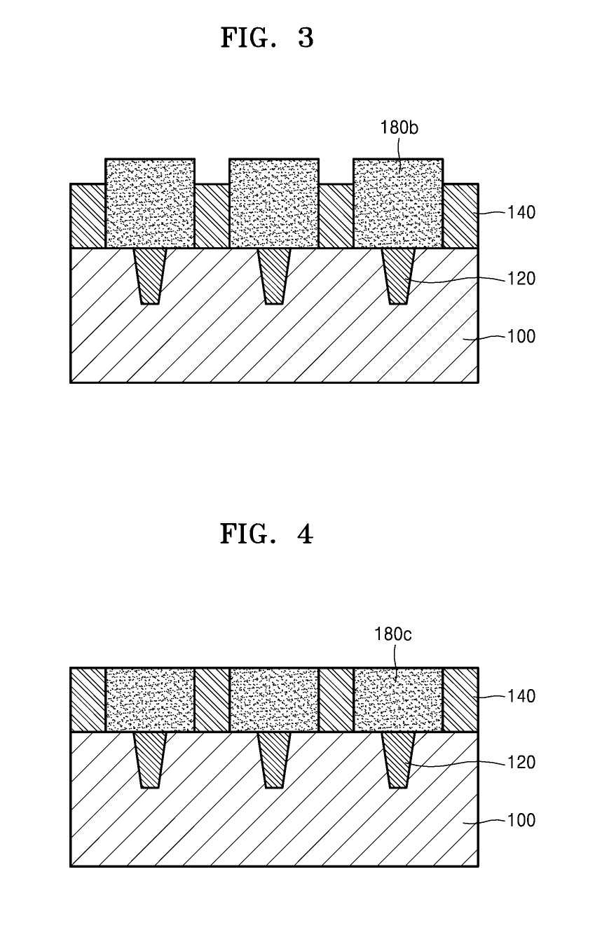

Results of Experimental examples 1 through 3 may be arranged as shown in FIG. 5.

FIG. 5 is a graph showing a polishing selectivity depending on the presence or absence of a silicon nitride layer polishing accelerator, a polysilicon (poly-Si) layer polishing inhibitor, and a silicon oxide layer polishing control agent.

Referring to FIG. 5, in the common slurry composition, a polishing selectivity for a silicon nitride layer to silicon oxide layer was 66:46, which was appropriate in terms of process characteristics because when an interlayer insulating layer formed on a gate mask was completely polished using a gate-last scheme, a polishing rate of the gate mask was higher than a polishing rate of the interlayer insulating layer so that the gate mask could be completely polished, and a dummy gate could serve as a polishing stop layer. In a semiconductor device fabrication process according to the inventive concepts, the polishing selectivity for the silicon nitride layer to the silicon oxide layer may range from 1:1 to 3:1.

In the common slurry composition, a polishing selectivity for a silicon nitride layer to a poly-Si layer was 66:1, which was appropriate in terms of process characteristics when the gate mask was formed on the dummy gate using a gate-last scheme. In the semiconductor device fabrication process according to the inventive concepts, the polishing selectivity for the silicon nitride layer to the poly-Si layer may range from 50:1 to 300:1.

In the common slurry composition, a polishing selectivity for a silicon oxide layer to a poly-Si layer was 46:1, which was appropriate in terms of process characteristics when the interlayer insulating layer was formed on side surfaces of the dummy gate using a gate-last scheme. In the semiconductor device fabrication process according to the inventive concepts, the polishing selectivity for the silicon oxide layer to the poly-Si layer may range from about 30:1 to about 200:1.

As a result, a method of fabricating a semiconductor device according to an example embodiment of the inventive concepts may include a first operation of forming an active region on a semiconductor substrate, a second operation of forming a plurality of poly-Si layer patterns on which a silicon nitride layer is formed, on the active region, a third operation of forming a silicon oxide layer on the silicon nitride layer, and a fourth operation of removing the silicon nitride layer and the silicon oxide layer using a one-time CMP process using a common slurry composition formed by adding about 0.1% by weight of threonine serving as polar amino acid, about 0.05% by weight of PEG, and about 0.1% by weight of 4-hydroxyethyl-2-pyrrolidone to a slurry in which a polishing agent contains about 1% by weight of ceria, until top surfaces of the poly-Si layer patterns are exposed.

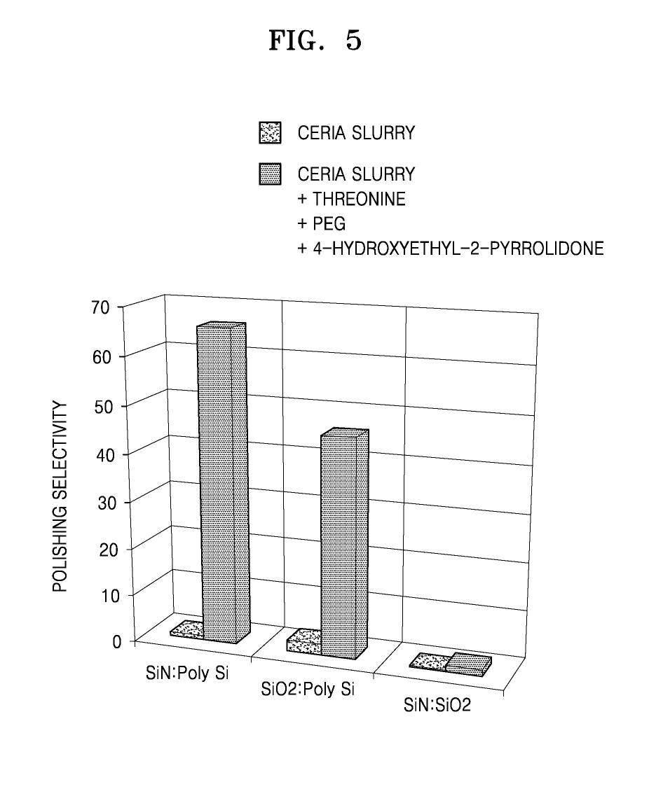

FIG. 6 is a circuit diagram of an inverter including a semiconductor device fabricated using a method of fabricating a semiconductor device according to an example embodiment of the inventive concepts.

Referring to FIG. 6, the inverter may include a complementary metal-oxide-semiconductor (CMOS) transistor including a transistor disposed in a p-type transistor region and a transistor disposed in an n-type transistor region. Each of the transistors disposed in the p-type transistor region and the transistor disposed in the n-type transistor region may include a fin field-effect transistor (FinFET) according to an example embodiment of the inventive concepts.

The transistor disposed in the p-type transistor region and the transistor disposed in the n-type transistor region may be connected in series between a driving voltage (Vdd) and a ground voltage (GND), and an input signal IN may be applied in common to a gate of the transistor disposed in the p-type transistor region and a gate of the transistor disposed in the n-type transistor region. Also, an output signal OUT may be output in common from a drain of the transistor disposed in the p-type transistor region and a drain of the transistor disposed in the n-type transistor region.

A driving voltage may be applied to a source of the transistor disposed in the p-type transistor region, and a ground voltage may be applied to a source of the transistor disposed in the n-type transistor region. A CMOS inverter may invert the input signal IN and generate the output signal OUT. In other words, when a logic level ‘1’ is input as an input signal of a logic level inverter, a logic level ‘0’ may be output as an output signal.

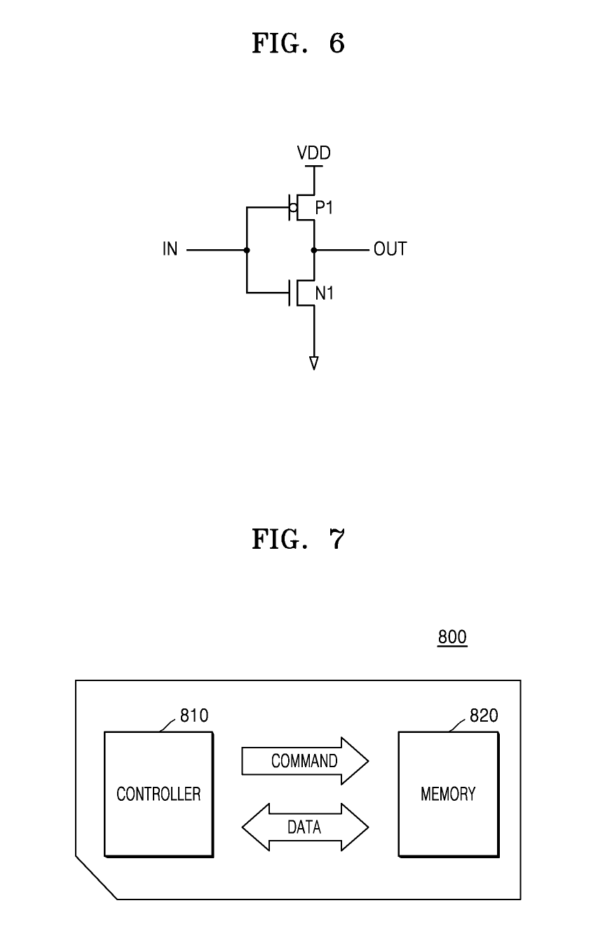

FIG. 7 is a schematic diagram of a card 800 including a semiconductor device fabricated using a method of fabricating a semiconductor device according to an example embodiment of the inventive concepts;

Specifically, in the card 800, a controller 810 and a memory 820 may be disposed to exchange electric signals. For example, when the controller 810 issues a command, the memory 820 may transmit data. The memory 820 or the controller 810 may include a semiconductor device according to an example embodiment of the inventive concepts. The card 800 may be one of various kinds of cards, for example, a memory stick card, a smart media (SM) card, a secure digital (SD) card, a mini SD card, or a multimedia card (MMC).

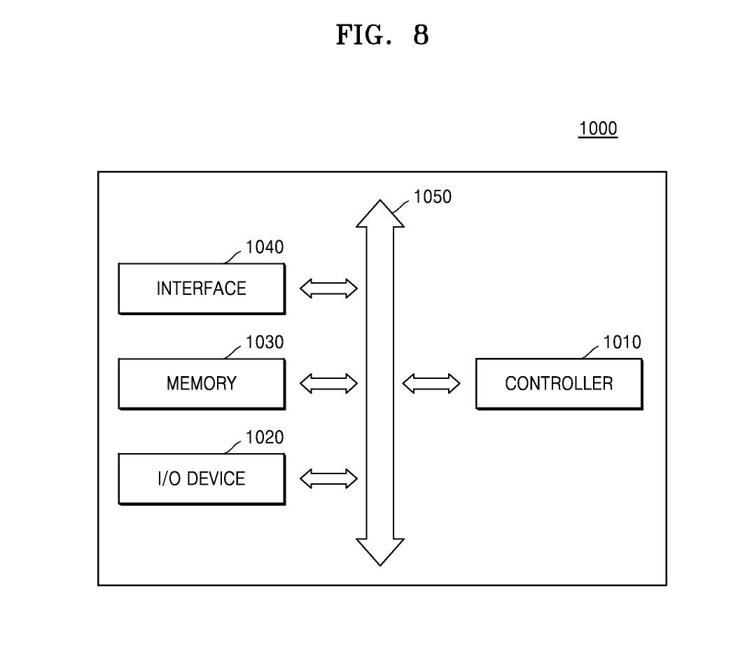

FIG. 8 is a schematic diagram of an electronic system 1000 including a semiconductor device fabricated using a method of fabricating a semiconductor device according to an example embodiment of the inventive concepts.

Specifically, the electronic system 1000 may include a controller 1010, an input/output (I/O) device 1020, a memory 1030, and an interface 1040. The electronic system 1000 may be a mobile system or a system configured to receive or transmit information. The mobile system may be a personal digital assistant (PDA), a portable computer, a web tablet, a wireless phone, a mobile phone, a digital music player, or a memory card.

The controller 1010 may execute a program, and the system 1100 may control the program. The controller 1010 may include a semiconductor device according to an example embodiment of the inventive concepts. The controller 1010 may be, for example, a microprocessor (MP), a digital signal processor (DSP), a microcontroller (MC), or devices similar thereto.

The I/O device 1020 may be used to input or output data to or from the electronic system 1000. The electronic system 1000 may be connected to an external device (e.g., a personal computer (PC) or a network) using the I/O device 1020 and exchange data with the external device. The I/O device 1020 may be, for example, a keypad, a keyboard, or a display device.

The memory 1030 may store codes and/or data for operations of the controller 1010, and/or store data processed by the controller 1010. The memory 1030 may include a semiconductor device according to an example embodiment of the inventive concepts. The interface 1040 may be a data transmission path between the electronic system 1000 and other external devices. The controller 1010, the I/O device 1020, the memory 1030, and the interface 1040 may communicate with one another through a bus 1050.

For instance, the electronic system 1000 may be used for a mobile phone, an MPEG-1 audio layer 3 (MP3) player, a navigation, a portable multimedia player (PMP), a solid-state disk (SSD), or household appliances.

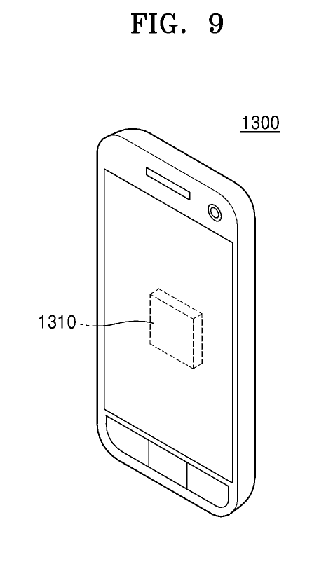

FIG. 9 is a schematic perspective view of an electronic device to which a semiconductor device fabricated using a method of fabricating a semiconductor device according to an example embodiment of the inventive concepts is applied.

Specifically, FIG. 9 illustrates a specific example in which the electronic system 1000 of FIG. 8 is applied to a mobile phone 1300. The mobile phone 1300 may include a system-on chip (SOC) 1310. The SOC 1310 may include a semiconductor device according to an example embodiment of the inventive concepts. The mobile phone 1300 may have relatively high performance because the mobile phone 1300 may include the SOC 1310 in which a highly efficient main function block may be disposed.

In addition, since the SOC 1310 may have relatively high performance over the same area, the mobile phone 1300 may be fabricated to have a minimum size and relatively high performance.

In an example embodiment of the present inventive concepts, a three dimensional (3D) memory array is provided. The 3D memory array is monolithically formed in one or more physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array.

In an example embodiment of the present inventive concepts, the 3D memory array includes vertical NAND strings that are vertically oriented such that at least one memory cell is located over another memory cell. The at least one memory cell may comprise a charge trap layer.

The following patent documents, which are hereby incorporated by reference, describe suitable configurations for three-dimensional memory arrays, in which the three-dimensional memory array is configured as a plurality of levels, with word lines and/or bit lines shared between levels: U.S. Pat. Nos. 7,679,133; 8,553,466; 8,654,587; 8,559,235; and US Pat. Pub. No. 2011/0233648.

While the inventive concepts have been particularly shown and described with reference to example embodiments thereof, it will be understood that various changes in form and details may be made therein without departing from the spirit and scope of the following claims.

What is claimed is:

1. A method of fabricating a semiconductor device, the method comprising:
forming an active region in a semiconductor substrate;
forming a plurality of dummy gates on the active region, the plurality of dummy gates having a gate mask disposed thereon;
forming an interlayer insulating layer on the gate mask; and
performing a one-time chemical mechanical polishing (CMP) process using a slurry composition capable of polishing the interlayer insulating layer and the gate mask until top surfaces of the dummy gates are exposed.

2. The method of claim 1, wherein
the forming a plurality of dummy gates forms the plurality of dummy gates having the gate mask including a silicon nitride layer disposed thereon,
the forming a plurality of dummy gates forms the dummy gates including polysilicon,
the forming an interlayer insulating layer forms the interlayer insulating layer including a silicon oxide layer, and
the performing uses the slurry composition including a polishing agent, a silicon nitride layer polishing accelerator, a polysilicon layer polishing inhibitor, a silicon oxide layer polishing control agent, a pH control agent, and a remaining percentage by weight of solvent.

3. The method of claim 1, wherein the performing uses the slurry composition having a polishing selectivity for a silicon nitride layer to a silicon oxide layer ranging from about 1:1 to about 3:1.

4. The method of claim 1, wherein the performing uses the slurry composition having a polishing selectivity for a silicon nitride layer to a polysilicon layer ranging from about 50:1 to about 300:1.

5. The method of claim 1, wherein the performing uses the slurry composition having a polishing selectivity for a silicon oxide layer to a polysilicon layer ranging from about 30:1 to about 200:1.

6. The method of claim 1, wherein the semiconductor device includes a three-dimensional memory array.

7. The method of claim 2, wherein the performing uses the polishing agent including at least one of silica particles, alumina particles, ceria particles, zirconia particles, and titania particles.

8. The method of claim 2, wherein the performing uses the silicon nitride layer polishing accelerator including at least one of isoleucine, alanine, glycine, glutamine, threonine, serine, asparagine, tyrosine, cysteine, valine, and leucine.

9. The method of claim 2, wherein the performing uses the silicon nitride layer polishing accelerator having a content of about 0.01% by weight to about 10% by weight in the slurry composition.

10. The method of claim 2, wherein the performing uses the polysilicon layer polishing inhibitor including at least one of polyvinyl alcohol (PVA), ethylene glycol (EG), glycerine, polyethylene glycol (PEG), polypropylene glycol (PPG), polyvinyl pyrrolidone (PVP), poly(acrylic acid) (PAA), ammonium salts of PAA, poly(methacrylic acid) (PMAA), ammonium salts of PMAA, polyacrylic maleic acid, an alkyl sodium sulfonate fluorosurfactant, a polyoxyethylene fluorosurfactant, and a nonionic ethoxylated fluorosurfactant.

11. The method of claim 2, wherein the performing uses the polysilicon layer polishing inhibitor having a content of about 0.0001% by weight to about 1% by weight in the slurry composition.

12. The method of claim 2, wherein the performing uses the silicon oxide layer polishing control agent including at least one of 1-2-hydroxyethyl-2-pyrrolidone, 4-hydroxyethyl-2-pyrrolidone, maleic anhydride, maleic hydrazide, and malemide.

13. The method of claim 2, wherein the performing uses the silicon oxide layer polishing control agent having a content of about 0.01% by weight to about 10% by weight in the slurry composition.

14. The method of claim 2, wherein the performing uses the pH control agent including at least one of ammonia, ammonium methyl propanol (AMP), tetra methyl ammonium hydroxide (TMAH), potassium hydroxide, sodium hydroxide, magnesium hydroxide, rubidium hydroxide, cesium hydroxide, sodium bicarbonate, sodium carbonate, triethanolamine, tromethamine, niacinamide, nitric acid, sulphuric acid, phosphoric acid, hydrochloric acid, acetic acid, citric acid, glutaric acid, glycolic acid, formic acid, lactic acid, malic acid, malonic acid, maleic acid, oxalic acid, phthalic acid, succinic acid, and tartaric acid.

15. A method of fabricating a semiconductor device, the method comprising:
forming an active region in a semiconductor substrate;
forming a plurality of polysilicon layer patterns on the active region, the plurality of polysilicon layer patterns having a silicon nitride layer disposed thereon;
forming a silicon oxide layer on the silicon nitride layer; and
performing a one-time chemical mechanical polishing (CMP) process using a slurry composition to remove the silicon nitride layer and the silicon oxide layer until a top surface of the polysilicon layer patterns are exposed, the slurry composition containing a polishing agent, a silicon nitride layer polishing accelerator, a polysilicon layer polishing inhibitor, a silicon oxide layer polishing control agent, a pH control agent, and a remaining percentage by weight of solvent.

16. A method of fabricating a semiconductor device, the method comprising:
forming a plurality of poly-Si patterns on a semiconductor substrate;
forming a silicon nitride layer on the plurality of poly-Si patterns;
forming a silicon oxide layer covering the silicon nitride layer and the semiconductor substrate; and
performing a chemical mechanical polishing (CMP) process using a slurry composition to remove the silicon nitride layer and the silicon oxide layer until top surfaces of the plurality of poly-Si patterns are exposed, the slurry composition having a higher polishing selectivity for the silicon nitride layer and the silicon oxide layer than for the poly-Si patterns.

17. The method of claim 16, wherein the performing uses the slurry composition including a polishing agent, a silicon nitride layer polishing accelerator, a polysilicon layer polishing inhibitor, a silicon oxide layer polishing control agent, a pH control agent, and a remaining percentage by weight of solvent.

18. The method of claim 16, wherein the performing uses the slurry composition having the polishing selectivity for the silicon nitride layer to the silicon oxide layer ranging from about 1:1 to about 3:1.

19. The method of claim 16, wherein the performing uses the slurry composition having the polishing selectivity for the silicon nitride layer to the poly-Si patterns ranging from about 50:1 to about 300:1.

20. The method of claim 16, wherein the performing uses the slurry composition having the polishing selectivity for the silicon oxide layer to the poly-Si patterns ranging from about 30:1 to about 200:1.
